(19) United States
(12) Patent Application Publication
(10) Pub. No.: US 2021/0139332 A1
(43) Pub. Date: May 13, 2021

(54) Nanowire-Mesh Templated Growth of Out-of-Plane Three-Dimensional Fuzzy Graphene

(71) Applicant: CARNEGIE MELLON UNIVERSITY, Pittsburgh, PA (US)

(72) Inventors: Raghav Garg, Pittsburgh, PA (US); Sahil Kumar Rastogi, Pittsburgh, PA (US); Tzahi Cohen-Karni, Pittsburgh, PA (US); Daniel J. San Roman, Pittsburgh, PA (US); Rahul Panat, Pittsburgh, PA (US)

(73) Assignee: CARNEGIE MELLON UNIVERSITY, Pittsburgh, PA (US)

(21) Appl. No.: 16/606,055

(22) PCT Filed: Apr. 17, 2018
(86) PCT No.: PCT/US18/28013

§ 371 Date: Oct. 17, 2019

Related U.S. Application Data
(60) Provisional application No. 62/602,218, filed on Apr. 17, 2017.

(51) Int. Cl. C01B 32/186; B33Y 80/00; C23C 16/50; C23C 16/26; C23C 16/52

(52) U.S. Cl. CPC C01B 32/186; B33Y 80/00; C23C 16/50; C01B 2204/04; C23C 16/52; C01B 2204/02; C23C 16/26

(57) ABSTRACT

Disclosed herein are methods of synthesizing a hybrid nanomaterial comprising 3D out-of-plane single- to few-layer fuzzy graphene on a scaffold, such as a Si nanowire mesh through a plasma-enhanced chemical vapor deposition process. By varying graphene growth conditions (CH4 partial pressure and process time), the size, density, and electrical properties of the hybrid nanomaterial can be controlled. Porous nanowire-templated 3D graphene hybrid nanomaterials exhibit high electrical conductivity and also demonstrate exceptional electrochemical functionality.

### CROSS-REFERENCE TO RELATED APPLICATIONS

This application claims the benefit under 35 U.S.C. § 119 of Provisional Application Ser. No. 62/602,218, filed Apr. 17, 2017, which is incorporated herein by reference.

### STATEMENT REGARDING FEDERALLY SPONSORED RESEARCH

This invention was made with Government support under National Science Foundation No. CBET1552833. The Government has certain rights in this invention.

### BACKGROUND OF THE INVENTION

Graphene, a honeycomb sp² hybridized two-dimensional (2D) carbon lattice, is a promising building block for hybrid-nanomaterials due to its chemical stability, electrical conductivity (charge carrier mobility up-to 200,000 cm² V⁻¹ s⁻¹), mechanical robustness (Young's modulus of ˜1 TPa), high surface-to-volume ratio (theoretical value of ˜2630 m² g⁻¹), and optical transparency (optical transmittance of ˜97.7%). Graphene can be readily obtained through mechanical exfoliation of highly-ordered pyrolithic graphite (HOPG), solution-based deposition of reduced graphene oxide (rGO), high temperature epitaxial growth on SiC, and chemical vapor deposition (CVD) on transition metal catalysts. The topology of the resulting graphene film (or flakes) obtained using any of these techniques is a 2D surface. Recently a three-dimensional (3D) topology of graphene (or rGO) has been demonstrated by various approaches, including, synthesis of graphene (or assembly of rGO) on nanoparticles followed by their organization in 3D; synthesis of graphene on Ge nanowires (NWs); synthesis of graphene on transition metal foams; and synthesis of 3D graphene hydrogels. In all these cases the graphene (or rGO) flakes or films are lying flat hence exposing a 2D surface topology.

An alternative approach to achieving 3D surface topology is to grow graphene flakes out-of-plane, i.e. vertical growth of graphene. This way, the graphene flakes are exposed and are not completely pinned to the underlying surface. In recent years, growth of out-of-plane carbon nanostructures appeared in numerous reports. Large area vertically aligned graphene sheets (VAGS) have been synthesized by thermal decomposition of SiC. In addition, by using plasma-enhanced CVD (PECVD) process, catalyst-free vertical growth of carbon nanowalls (CNWs) was achieved. The obtained VAGS and CNWs are composed of few to dozens graphene layers, and therefore are more similar to graphite than to single- or few-layer graphene nanostructures. Moreover, these VAGS and CNWs are still pinned to a 2D surface. It would therefore be advantageous to develop a method of fabricating 3D out-of-plane growth graphene hybrid-nanomaterials that leverage graphene's outstanding surface-to-volume ratio.

### BRIEF SUMMARY

According to embodiments of the present invention is a method of synthesizing highly controlled out-of-plane single- to few-layer 3D fuzzy graphene (3DFG) on a 3D Si nanowire (SiNW) mesh template or other three-dimensional structure. In certain embodiments, the graphene growth conditions (such as CH₄ partial pressure and process time) are varied to control the size, density, electrical, and electrochemical properties of the nanowire-templated 3DFG (NT-3DFG). This flexible synthesis can result in complex hybrid-nanomaterials with unique optical and electrical properties to be used in applications such as sensing, and energy conversion and storage.

### BRIEF SUMMARY OF THE SEVERAL VIEWS OF THE DRAWINGS

FIGS. 1A-1B are flowcharts depicting a method of synthesizing NT-3DFG, according to alternative embodiments.

FIGS. 2A-2G are scanning electron microscope images of NT-3DFG hybrid nanomaterial synthesized under various conditions.

FIG. 3 is a graph showing NT-3DFG diameter as a function of CH4 partial pressure with 10 min PECVD process time (circles) and PECVD process time under 25.0 mTorr CH₄ partial pressure (squares).

FIGS. 4A-4C are graphs showing Raman spectra for NT-3DFG hybrid nanomaterial synthesized under various conditions.

FIGS. 5A-5D are images of NT-3DFG synthesized according to various embodiments.

FIGS. 6A-6B are graphs showing properties of the NT-3DFG hybrid nanomaterial synthesized according to one embodiment.

FIG. 7 is a graph showing electrical properties of the NT-3DFG hybrid nanomaterial synthesized according to one embodiment.

FIGS. 8A-8B are graphs depicting the electrical properties of the NT-3DFG hybrid nanomaterial synthesized according to embodiments of the method of the present invention.

FIGS. 9A-9B show example electrodes created with the NT-3DFG hybrid nanomaterial created by the method of the present invention.

### DETAILED DESCRIPTION

In one embodiment, a nanowire-templated three-dimensional fuzzy graphene (NT-3DFG) hybrid nanomaterial 100 was synthesized using a three-step process, as presented in FIG. 1A. In the first step, silicon nanowires (SiNWs) 201 were synthesized by Au nanoparticle (AuNP) catalyzed vapor-liquid-solid (VLS) process. Next, the SiNWs 201 were collapsed using capillary forces by flowing liquid N₂ and annealed in H₂ to form an interconnected mesh, forming a scaffold 202 on which the three-dimensional fuzzy graphene (3DFG) 203 will be grown. Finally, 3DFG 203 is grown on the three-dimensional SiNWs-based mesh, or scaffold 202, through inductively coupled plasma-enhanced chemical vapor deposition (PECVD) process.

Referring again to the first step depicted in FIG. 1A, SiNWs 201 were synthesized by an AuNP catalyzed VLS growth process. In one example embodiment, either a 1.5 cm by 2.0 cm Si substrate with a 600 nm wet thermal oxide (p-type, ≤0.005 Ω cm, Nova Electronic Materials Ltd., catalog no. CP02 11208-OX) or 1.5 cm by 1.5 cm or 1.5 cm by 2.0 cm fused silica substrate (University Wafer, catalog no. 1013, fused silica was used for electrical and electrochemical measurements) was cleaned with acetone and isopropyl alcohol (IPA) in an ultrasonic bath for 5 min each, and N₂ blow-dried. The substrate was placed in a UV-ozone system (PSD Pro series digital UV-Ozone, Novascan) for 10 min at 150° C. The substrate was then functionalized with 450 μL (400 μL for 1.5 cm by 1.5 cm substrate) of 4:1 deionized (DI) water:poly-L-lysine (PLL) (0.1% w/v, Sigma-Aldrich, catalog no. P8920) for 8 min. Following this step, the substrate was gently washed three times in DI-water and N₂ blow-dried. 450 μL (400 μL for 1.5 cm by 1.5 cm substrate) of 30 nm AuNP solution (Ted Pella, Inc., catalog no. 15706-1) was dispersed onto the PLL coated substrate for 8 min. The substrate was gently washed three times in DI-water, N₂ blow-dried, and introduced into a chemical vapor deposition setup. Once a baseline pressure of 1*10⁻⁵ Torr was reached, the temperature was ramped up to 450° C. in 8 min, followed by a 5 min stabilization step. Nucleation was conducted at 450° C. for 15 min with 80 standard cubic centimeters per minute (sccm) H₂ (Matheson Gas) and 20 sccm SiH₄ (10% in H₂, Matheson Gas) at 40 Torr. This was followed by a growth step of 100 min with 60 sccm H₂, 20 sccm SiH₄ and 20 sccm PH₃ (1000 ppm in H₂, Matheson Gas) at 40 Torr. The sample was then rapidly cooled down to room temperature at base pressure.

To create a scaffold 202 from the SiNWs 201, the synthesized SiNWs 201 are collapsed by flowing liquid N₂ into the chemical vapor deposition quartz tube under 200 sccm Ar flow. By collapsing the SiNWs 201, individual wires collapsed onto neighboring wires, forming a mesh pattern, or three-dimensional structure. The system is evacuated to base pressure followed by a 10 min annealing step at 800° C. under 200 sccm H₂ flow at 1.6 Torr. Finally, the system is rapidly cooled to room temperature.

In an alternative embodiment, the scaffold 202 comprises a microlattice template 204, with regular or irregular arrangements. The microlattice template 204, as shown in FIG. 1B, can be formed by methods such as nanoparticle printing of precursor materials or other methods known in the art, such as aerosol jet printing, inkjet printing, laser writing, and additive manufacturing techniques. The surface of the microlattice template 204 can be modified by chemical or physical treatment, such as electroless deposition, electrodeposition, physical vapor deposition, chemical vapor deposition, or direct solution immersion, for example, to place precursor material to facilitate deposition of 3DFG 203. The precursor materials can be metallic (such as Ag, Au, Si, SiO2, Cu, CuNi, Pt), ceramic (W2O3, ZnO, alumina, and barium titanate), or polymer (polystyrene and acrylated urethane). The microlattice template 204 can be used directly as the scaffold 202, or nanowires can be grown from the surface, as shown in FIG. 1B. FIG. 2F shows a hybrid nanomaterial 100 created from a microlattice template 204.

In yet another alternative embodiment, the 3DFG 203 is grown on a scaffold 202 comprising carbonized silk nanofibers (derived from silk fibroin), as shown in FIG. 2G. Moreover, 3DFG 203 can be synthesized on a variety of substrates based on the application. That is, the process of growing 3DFG 203 is substrate independent.

Once a scaffold 202 is provided, 3DFG 203 is synthesized by a PECVD process in which the 3DFG 203 is grown on the scaffold 202. In one example embodiment, the SiNW mesh scaffold 202 is taken from the CVD process and introduced into a custom-built PECVD setup. In this example embodiment, the synthesis process is carried out at 800° C. and at a total pressure of 0.5 Torr. The mesh scaffold 202 is placed onto a carrier wafer to position it at the center of a tube in the PECVD setup and is placed 4.0 cm from the edge of an RF coil. The temperature is ramped up to 800° C. in 13 min, followed by stabilization at 800° C. for 5 min, under a flow of 100 sccm Ar (Matheson Gas). Inductively coupled plasma is generated using a 13.56 MHz RF power supply (AG 0313 Generator and AIT-600 RF, power supply and auto tuner, respectively, T&C Power Conversion, Inc.). The plasma power is kept constant at 50 W. The furnace is moved over the sample following plasma ignition. The synthesis step is conducted by either varying the flow ratios of CH₄ precursor (5% CH₄ in Ar, Airgas) and H₂ (Matheson Gas), or the process time. Table 1 summarizes the conditions of the synthesis processes (three independently synthesized samples, n=3, were performed for each reported condition). The plasma is shut down after the synthesis step and the NT-3DFG hybrid nanomaterial 100 is rapidly cooled from growth temperature to 80° C. in 30 min under 100 sccm Ar flow.

The effect of varying PECVD conditions, i.e., CH₄ partial pressure and PECVD process time, on the growth of 3DFG 203 is summarized in Table 1. Scanning electron microscope (SEM) images reveal that varying the CH4 partial pressure affects both the density and size of the 3DFG 203 grown on the scaffold 202. At CH₄ partial pressure of 20.0 mTorr (FIG. 2A), by SEM imaging there are no noticeable 3DFG flakes 203 on individual SiNWs 201 of the scaffold 202 as compared to pristine SiNW mesh. As the CH₄ partial pressure increases to 22.7 mTorr (FIG. 2B) and 25.0 mTorr (FIG. 2C), the density of 3DFG flakes 203 on the individual SiNWs 201 of the scaffold 202 increases along with the size of the flakes 203, as indicated by the increasing average diameter (37±6 nm, 38±4 nm, 67±6 nm and 163±22 nm at 8.3 mTorr, 20.0 mTorr, 22.7 mTorr and 25.0 mTorr CH₄ partial pressure, respectively) (see FIG. 3). The notable increase in 3DFG density on the scaffold 202 can be attributed to the increase in CH₄ partial pressure and decrease in the ratio of H/C radical density in the PECVD gas feed. Increase in the PECVD process time or duration (under 25.0 mTorr CH₄ partial pressure) also leads to an increase in the size of the flakes (79±9, 163±22 nm, 464±25 nm, and 1549±184 nm for 5 min, 10 min, 30 min, and 90 min, respectively) (FIGS. 2D-2E). 3DFG flakes 203 are oriented out of the surface of the SiNW mesh scaffold 202, and consistent throughout NT-3DFG hybrid nanomaterial 100 as observed in FIGS. 2B-2E. The NT-3DFG hybrid nanomaterial 100 thickness is 7.2±1.9 μm. Energy dispersive spectroscopy (EDS) confirms the elemental composition of the synthesized hybrid nanomaterial 100 as a Si core with a conformal coating of carbon flakes.

TABLE 1

| | | | Total | 5% CH₄ | H₂ | |
|---|---|---|---|---|---|---|
| NT-3DFG | | Temperature | Pressure | Flow | Flow | Time |
| condition | | (° C.) | (Torr) | (sccm) | (sccm) | (min) |
| SiNWmesh | | — | — | — | — | — |
| 8.3 | mTorr | 800 | 0.5 | 50 | 100 | 10 |
| 20.0 | mTorr | 800 | 0.5 | 40 | 10 | 10 |
| 22.7 | mTorr | 800 | 0.5 | 50 | 5 | 10 |
| 25.0 | mTorr | 800 | 0.5 | 50 | 0 | 10 |
| 5 | min | 800 | 0.5 | 50 | 0 | 5 |
| 10 | min | 800 | 0.5 | 50 | 0 | 10 |
| 30 | min | 800 | 0.5 | 50 | 0 | 30 |
| 90 | min | 800 | 0.5 | 50 | 0 | 90 |

Details regarding the nature of the carbon flakes can be gleaned from Raman spectroscopy (FIGS. 4A-4C). The characteristic peaks in the Raman spectra, i.e. D, G and 2D peaks, are analyzed to corroborate the presence of graphene (FIG. 4A). In FIG. 4A, the top graph depicts Raman spectra of NT-3DFG synthesized under various CH₄ partial pressures (i.e. 20.0 mTorr, 22.7 mTorr, and 25.0 mTorr) for 10 min. The bottom graph depicts Raman spectra of NT-3DFG hybrid nanomaterial 100 synthesized under a 25.0 mTorr CH₄ partial pressure for various PECVD process times of 5 min, 30 min, and 90 min. The G peak shows a red-shift with increasing CH₄ partial pressure, implying progression of nano-crystalline graphene. The D and D′ peaks are produced due to one-phonon defect-assisted process, and D+D′ peak is produced due to two-phonon defect-assisted process. In the case of 3DFG 203, the emergence of the D peak, at ca. 1335 cm⁻¹, and the D′ peak, as a shoulder to the G peak, is caused by breaks in translational symmetry due to the presence of 3DFG edges, as evident in the SEM images (FIGS. 2A-2E). Emergence of such edge defects leads to broader peaks relative to defect free single-layer graphene. The observed broad 2D peak can be fitted with a single Lorentzian (FIG. 4A), and explained by the presence of juxtaposed single- to few-layer graphene flakes, in the form of high-density 3DFG 203. In the case of NT-3DFG hybrid nanomaterial 100 synthesized under 20.0 mTorr CH₄ partial pressure for 10 min, and 25.0 mTorr CH₄ partial pressure for 5 min, blue shift of ca. 20 cm⁻¹ in the position of the 2D peak and further broadening of the 2D peak, as compared to other PECVD conditions, indicate the presence of folded, misoriented and turbostratic graphene (FIG. 4A). The increase in I_{D}/I_{G} and I_{2D}/I_{G} with increasing CH₄ partial pressure (FIG. 4B) can be attributed to the increase in edge density. However, NT-3DFG hybrid nanomaterial 100 synthesized under 25.0 mTorr CH₄ partial pressure with increasing PECVD process times (10 min, 30 min and 90 min) do not show change in the position of the G and 2D peaks, I_{D}/I_{G}, I_{2D}/I_{G}, and 2D peak full width at half maximum (FWHM(2D)). This can be attributed to the high density of 3DFG flakes 203 when compared to other synthesis conditions. Increase in the density of 3DFG 203 reduces the average distance covered by an electron-hole pair before scattering, which is evident through the saturation of I_{D}/I_{G} with increasing 3DFG density as a result of increasing PECVD process time (FIG. 4B).

The appearance of a strong D peak due to edge effects was further verified by dual-wavelength Raman spectroscopy. Increase in both the position of the G peak as a function of excitation wavelength (Disp(G)) and G peak full width at half maximum (FWHM(G)) is observed with an increase in the disorder in the carbon structure. Therefore, a higher I_{D}/I_{G} corresponds to higher Disp(G) and FWHM(G) in the case of bulk structural defects, thus facilitating the discrimination between disorder at the edges and in the bulk. The lack of clear correlation between I_{D}/I_{G} and FWHM(G) as well as I_{D}/I_{G} and Disp(G) (FIG. 4C) further corroborates that the major contribution to the D peak is due to edge defects rather than bulk-structural defects. The saturation of Disp(G) at ca. 1600 cm⁻¹ with change in excitation wavelength is another indication of the presence of sp² hybridization and lack of large structural defects.

The structure and growth progression of NT-3DFG hybrid nanomaterial 100 were further explored using aberration-corrected transmission electron microscope (Cₛ-TEM) (FIGS. 5A-5D). At 20.0 mTorr CH₄ partial pressure grown NT-3DFG hybrid nanomaterial 100, a distinct conformal coating of graphene sheath with folds is observed around the SiNW 201 core (FIG. 5A). This observation agrees with the obtained Raman spectroscopy data. It is also apparent that there are few-layer graphene nano-flakes 203 growing from the surface of the SiNW 201 (FIG. 5A, arrows). As the carbon content in the PECVD process increases (through increase in CH₄ partial pressure), larger single- to few-layer 3DFG flakes 203 are observed (FIGS. 5B-5C). The flakes 203 extend out of the SiNW 201 surface as seen in FIG. 5C (inset), and a distinguishable border between the Si scaffold 202 and graphene flakes 203 is observed. Extension of the process time, under 25.0 mTorr CH₄ partial pressure, from 10 min to 30 min results in an increase in both graphene edge density and size (FIG. 5C-5D). Selected area electron diffraction (SAED) data indicates that 3DFG 203 is polycrystalline in nature (FIG. 5D (inset)). The interplanar distances for the 1^{st} and 2^{nd} nearest C-C neighbors were experimentally derived to be 0.119 nm and 0.205 nm. These values agree with the expected inter-planar spacing for the (112̅0) plane (d_{112̅0}=0.123 nm) and the (101̅0) plane (d_{101̅0}=0.213 nm). The distance between individual graphene layers (d₀₀₀₂=0.350 nm) concurs with the expected value of 0.344 nm (FIG. 5B, 5C (lines), and FIGS. 6A-6B) indicating the presence of turbostratic graphene.

Electron energy loss spectroscopy (EELS) C K(1s) analysis yields a sharp peak at 285.5 eV due to 1 s to π* transition and a broader peak in the 290-310 eV region due to 1 s to σ* transition. Extended fine structure analysis of EELS spectra acquired from a NT-3DFG (25.0 mTorr CH₄ partial pressure for 30 min) shows the presence of graphite-like material near the center and isolated single-layer graphene near the edge (FIG. 7). As can be seen in the scanning transmission electron microscope (STEM) images, the centre of the NT-3DFG is composed of dense 3DFG flakes compared to the edge, where the incident beam interacts with single-layer 3DFG. Such a closely packed arrangement at the center of the NT-3DFG, will generate EELS spectra resembling graphite-like material.

The NT-3DFG hybrid nanomaterial 100 can be used as an electrical and an electrochemical platform. The electrical properties of the material 100 can be measured by determining the sheet resistance of the NT-3DFG hybrid nanomaterial 100 through the van der Pauw method. The sheet resistance of NT-3DFG hybrid nanomaterial 100 decreases with increasing CH₄ partial pressure and PECVD process time (FIGS. 8A-8B). This change in the sheet resistance is attributed to the increasing density of single- to few-layer 3DFG flakes 203, which leads to the ability to sustain large current densities. The lowest sheet resistance value measured is for the 90 min PECVD process (84±6 Ω□⁻¹, conductivity of 1655±450 S m⁻¹). This value is much lower than published sheet resistance of polycrystalline graphene films. Furthermore, HNO3 treatment reduces the sheet resistance of NT-3DFG hybrid nanomaterial 100 to 59±12 Ω□⁻¹, (conductivity of 2355±785 S m⁻¹) by increasing carrier concentration. The determined electrical conductivity of NT-3DFG hybrid nanomaterial 100 exceeds literature reported values for 3D graphene nanostructures and 3D graphene composites (Table 2, shown below). In these measurements, NT-3DFG hybrid nanomaterial 100 is assumed to be a continuous surface without any pores. Porosity correction will further reduce the observed sheet resistance values (thus increase conductivity).

NT-3DFG hybrid nanomaterial 100 was further used as an electrode in a three-electrode electrochemical cell. Prior to these experiments, the surface wettability was evaluated by measuring the contact angle, θ, of different synthesized materials. Compared to both low pressure CVD (LPCVD) synthesized single-layer graphene film transferred to Si/600 nm SiO₂ (θ≈90°) and pristine SiNW mesh (θ≈0°, since the mesh absorbed the water droplet), NT-3DFG hybrid nanomaterial 100 is a super-hydrophobic material (θ≈155°). Although single-layer graphene film does not exhibit super-hydrophobicity, the combination of graphene and nanoscale edges makes the surface super-hydrophobic. The super-hydrophobicity of NT-3DFG hybrid nanomaterial 100 can be explained by the Cassie-Baxter model of porous surface wettability. Briefly, the presence of air pockets between the 3DFG flakes 203 allows for the deionized water droplet to be suspended on 3DFG edges.

The faradaic redox peak currents increase for NT-3DFG hybrid nanomaterial 100 compared to planar Au working electrode. This is attributed to the increase in the electrochemically active surface area due to the presence of 3DFG 203. Treating NT-3DFG hybrid nanomaterial 100 with HNO₃ further increases the peak currents due to change in the surface wettability from super-hydrophobic to hydrophilic. SEM imaging and Raman spectroscopy analysis reveal that HNO₃ treatment does not alter physical characteristics of NT-3DFG hybrid nanomaterial 100. Both anodic and cathodic faradaic peak currents increase linearly with increasing square-root of scan rate and increasing [Fe(CN)₆]³⁻ concentration. These results are in good agreement with the Randles-Sevc̆ik model and establish that diffusion is the sole means of mass transport for NT-3DFG hybrid nanomaterial 100 electrodes. Increase in the slope of the peak current vs. square root of scan rate curve (Au<NT-3DFG<HNO₃ treated NT-3DFG hybrid nanomaterial 100) further supports the increase in electrochemically active surface area. Faradaic peak separation for 90 min NT-3DFG (ca. 0.12 V) is smaller than that observed for 30 min NT-3DFG (ca. 0.30 V). This is attributed to faster electron transfer rates in 90 min NT-3DFG when compared to 30 min NT-3DFG hybrid nanomaterial 100.

The double-layer capacitance of the working electrode was calculated as the change in current density with respect to the scan rate. The double-layer capacitance of NT-3DFG hybrid nanomaterial 100 (0.56±0.01 mF cm⁻² and 1.85±0.02 mF cm⁻² for 30 min and 90 min NT-3DFG, respectively) is higher than that of Au working electrode (0.009±0.001 mF cm⁻²) due to the remarkably high surface area of NT-3DFG hybrid nanomaterial 100 (calculated specific electrochemical surface area of 117±13 m² g⁻¹ and 340±42 m² g⁻¹ for 30 min and 90 min NT-3DFG, respectively). HNO₃ treatment significantly increases the double-layer capacitance of NT-3DFG hybrid nanomaterial 100 (2.25±0.07 mF cm⁻² and 6.50±0.10 mF cm⁻² for 30 min and 90 min NT-3DFG hybrid nanomaterial 100, respectively; calculated specific electrochemical surface area of 472±53 m² g⁻¹ and 1017±127 m² g⁻¹ for 30 min and 90 min NT-3DFG hybrid nanomaterial 100, respectively). This is attributed to enhanced wettability and exceptional pseudocapacitance of 3DFG 203 due to introduction of oxide-containing species through redox reactions. Electrochemical surface area for NT-3DFG hybrid nanomaterial 100 electrodes was determined by computing the capacitance ratios of the electrodes with respect to the Au working electrode. The calculated electrochemical surface area represents a lower value range compared to nitrogen adsorption experiments. Nonetheless, the determined electrochemical surface area values exceed literature reported surface area values for 3D carbon based electrode materials such as graphene foam, 3D macroporous chemically modified graphene (CMG) electrodes, graphene aerogel, and carbon nanotube (CNT) based platforms (such as composites, graphene-SWCNT gels, films and electrodes) (Table 2). NT-3DFG hybrid nanomaterial 100 electrodes maintain their electrochemical performance for over a month, implying stable electrochemical and corrosion-resistive properties of 3DFG 203.

TABLE 2
Surface area and electrical conductivity
of various carbon-based materials.

| | | Electrical |
|---|---|---|
| | Surface area | conductivity |
| Material | (m² g⁻¹) | (S m⁻¹) |
| NT-3DFG hybrid | 1017 | 2400 |
| nanomaterial 100 | | |
| Graphene foams | 850 | 1000 |
| CMG agglomerates | 705 | 200 |
| 3D macro-porous CMG | 194.2 | 1204 |
| electrodes | | |
| Graphene aerogels | 584 | 100 |
| 3D porous rGO films | — | 1905 |
| Graphene-SWCNT cogels | 800 | 20 |
| Graphene coated SWCNT gels | 686 | — |
| CNT films and electrodes | 120-500 | — |
| CNT-MnO₂ composites | 234 | — |

The foregoing demonstrates the unique synthesis of novel hybrid-nanomaterial of out-of-plane single- to few-layer 3DFG 203 on a scaffold 202, such as a SiNW 201 mesh. The density and size of out-of-plane graphene flakes 203 is closely controlled by varying CH₄ partial pressure and PECVD process time. Through Raman spectroscopy, electron microscopy (SEM and TEM), and EELS, the flakes were characterized, and consist of single- to few-layer graphene with a high density of exposed graphene edges. The out-of-plane structure of 3DFG 203 confers superhydrophobic properties to the material. As-synthesized NT-3DFG hybrid nanomaterial 100 demonstrates exceptional electrical conductivity of 1655±450 S m⁻¹ (84±6 Ω□⁻¹). Treatment with HNO₃ renders the super hydrophobic surface as hydrophilic and further increases the electrical conductivity to 2355±785 S m⁻¹ (59±12 Ω□⁻¹). NT-3DFG hybrid nanomaterial 100 electrodes demonstrate functionality in an electrochemical cell model wherein the material exhibits enhanced faradaic peak currents, capacitance, and electrochemical surface area up to 1017±127 m² g⁻¹ upon HNO₃ treatment. Furthermore, NT-3DFG hybrid nanomaterial 100 electrodes show electrochemical stability for more than a month. Stability of NT-3DFG hybrid nanomaterial 100 electrode surface was determined by plotting the anodic peak current (with 5.00 mM [Fe(CN)₆]³⁻ in 1M KCl solution at a scan rate of 50 mV s⁻¹) against the number of days (1, 3, 5, 7, 14, 21, 28, 35, 42 and 49). Example electrodes are shown in FIGS. 9A-9B.

While the disclosure has been described in detail and with reference to specific embodiments thereof, it will be apparent to one skilled in the art that various changes and modification can be made therein without departing from the spirit and scope of the embodiments. Thus, it is intended that the present disclosure cover the modifications and variations of this disclosure provided they come within the scope of the appended claims and their equivalents.

What is claimed is:

1. A method of fabricating a three-dimensional fuzzy graphene hybrid nanomaterial comprising:
providing a scaffold having a three-dimensional surface; and
growing fuzzy graphene on the scaffold in a plasma-enhanced chemical vapor deposition process,
wherein the fuzzy graphene is grown out-of-plane from a surface of the scaffold.

2. The method of claim 1, wherein providing the scaffold comprises:
synthesizing silicon nanowires using an Au catalyzed vapor-liquid-solid process;
collapsing the silicon nanowires into a mesh using capillary forces by flowing liquid N₂; and
annealing the mesh in H₂.

3. The method of claim 1, wherein fabricating the scaffold comprises:
providing a microlattice with precursor materials.

4. The method of claim 1, wherein the fuzzy graphene is grown in a single layer.

5. The method of claim 1, wherein the fuzzy graphene is grown in a plurality of layers.

6. The method of claim 1, wherein growing fuzzy graphene on the scaffold comprises:
controlling the flow ratio of at least one of CH4 and H₂.

7. The method of claim 1, wherein growing fuzzy graphene on the scaffold comprises:
adjusting the partial pressure of CH₄.

8. The method of claim 1, wherein growing fuzzy graphene on the scaffold comprises:
controlling a duration of the plasma-enhanced chemical vapor deposition process.

9. The method of claim 1, further comprising:
increasing the wetability of the three-dimensional fuzzy graphene hybrid nanomaterial.

10. The method of claim 9, wherein increasing the wetability comprises treating the hybrid nanomaterial with HNO₃.

11. The method of claim 1, wherein the scaffold comprises a mesh formed from a plurality of nanowires.

12. The method of claim 1, wherein the plurality of nanowires comprise silicon.

13. The method of claim 1, wherein the scaffold comprises a microlattice template.

14. The method of claim 13, wherein the microlattice template is formed from a process selected from the group consisting of aerosol jet printing, inkjet printing, laser writing, and additive manufacturing.

15. A hybrid nanomaterial produced by any of claims 1-14.

16. A hybrid nanomaterial comprising:
a substrate having a surface;
a plurality of graphene flakes extending from the surface of the substrate.

17. The hybrid nanomaterial of claim 16, wherein the plurality of graphene flakes have a vertical orientation to the surface of the substrate.

18. The hybrid nanomaterial of claim 16, wherein the substrate is selected from the group consisting of silicon nanowires, a microlattice, and carbonized silk.
